(19) United States
(12) Patent Application Publication
(10) Pub. No.: US 2017/0202079 A1
(43) Pub. Date: Jul. 13, 2017

(54) BOLSTER PLATE

(71) Applicant: HEWLETT PACKARD ENTERPRISE DEVELOPMENT LP, Houston, TX (US)

(72) Inventors: John NORTON, Houston, TX (US); Joseph ALLEN, Tomball, TX (US)

(21) Appl. No.: 15/314,077

(22) PCT Filed: Jun. 25, 2014
(86) PCT No.: PCT/US14/44104

§ 371 Date: Nov. 26, 2016

(51) Int. Cl. H05K 1/02; H01L 23/40

(52) U.S. Cl. CPC H05K 1/0271; H01L 23/4006; H05K 1/0203

(57) ABSTRACT

Example implementations relate to a bolster plate. One example bolster plate includes a first member having a first height. The first member is substantially uniform in height. The bolster plate also includes a second member connected to the first member. The second member includes a base region having the first height and a raised region extending from the base region. The raised region has a second height that is greater than the first height. The bolster plate further includes a third member connected to the second member and a fourth member connected to the third member and to the first member.

### BACKGROUND

A semiconductor device, such as a processor, generates heat during operation. The heat increases the temperature of the semiconductor device. Increasing temperature of a semiconductor device may lead to malfunctioning of the semiconductor device. To remove the heat generated during operation, a cooling device, such as a heat sink, may be used.

### BRIEF DESCRIPTION OF THE DRAWINGS

Some examples of the present application are described with respect to the following figures:

FIG. 1 is a top view of a bolster plate, according to an example;

FIG. 2 is a top view of a bolster plate, according to another example;

FIG. 3A is a cross-section of a member of a bolster plate, according to an example;

FIG. 3B is a cross-section of a member of a bolster plate having a base region and a raised region, according to an example; and

FIG. 4 is a cross-section of a member of a bolster plate having a base region and a raised region, according to another example.

### DETAILED DESCRIPTION

As described above, to remove the heat generated by a semiconductor device during operation, a cooling device, such as a heat sink, may be used. The cooling device may be attached to the semiconductor device to draw heat away from the semiconductor device. To attach a cooling device to a semiconductor device, such as a processor, the heat sink may be mounted to a printed circuit board that houses the semiconductor device.

When a cooling device is being mounted to the printed circuit board, the printed circuit board may experience a downward force, and the printed circuit board may bend due to the downward force. Thus, the printed circuit board may be damaged due to bending.

Examples described herein address reduce the likelihood of damage caused by mounting forces by providing a bolster plate to reduce the amount of mounting force experienced by the printed circuit board. For example, a bolster plate may include a first member having a first height. The first member may be substantially uniform in height. The bolster plate may also include a second member connected to the first member. The second member may include a base region having the first height and a raised region extending from the base region. The raised region may have a second height that is greater than the first height. The raised region may increase the structural rigidity of the second member. Thus, the raised region may reduce a likelihood of bending of the second member. The bolster plate may further include a third member connected to the second member and a fourth member connected to the third member and to the first member. The fourth member may include a raised region similar to the raised region of the second member. In this manner, examples described herein may reduce a likelihood of damaging a printed circuit board due to the mounting force of a heat sink.

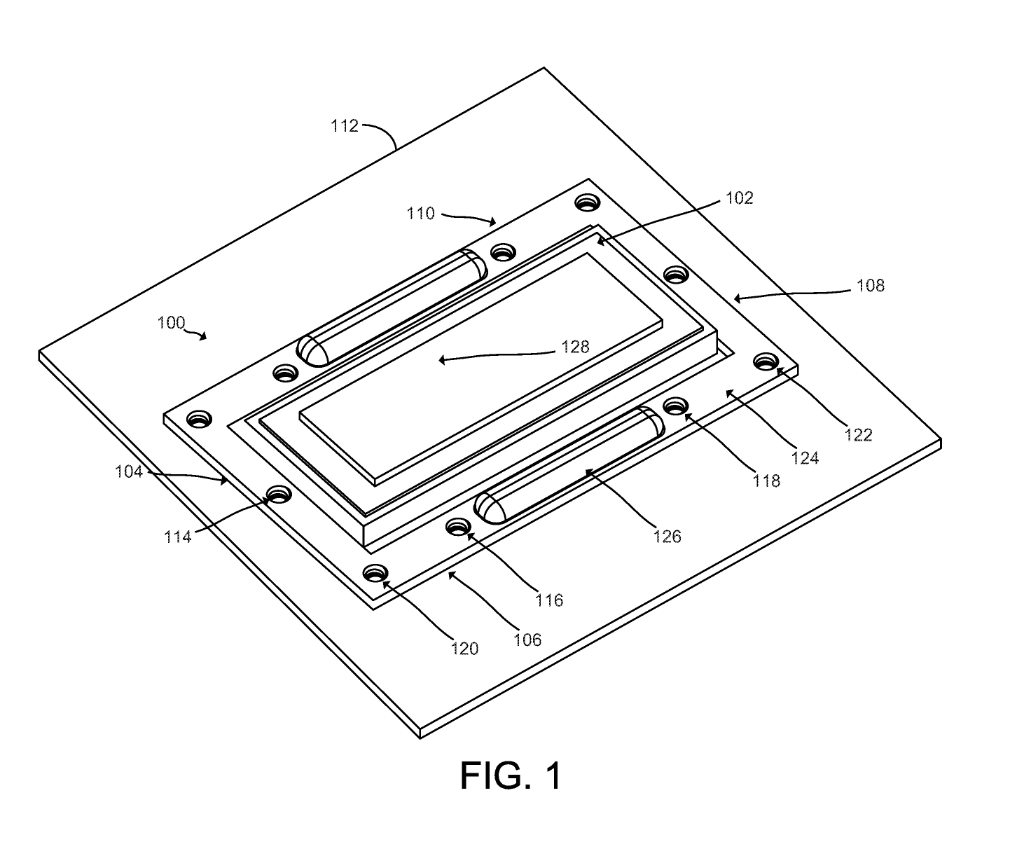

Referring now to the figures, FIG. 1 is a front view of a bolster plate 100 with a raised region, according to an example. As used herein, a bolster plate may be any device that is suitable to provide structural support to a portion of a printed circuit board that houses a semiconductor device attached to cooling device, such as a heat sink. Bolster plate 100 may be shaped to surround a semiconductor device 102 to receive a cooling device (not shown in FIG. 1) of semiconductor device 102. Thus, bolster plate 100 may have a shape similar to semiconductor device 102. For example, semiconductor device 102 may have a rectangular shape and bolster plate 100 may also have a rectangular shape. Semiconductor device 102 may be, for example, a processor, a memory module, or any other semiconductor device that may reduce operating temperature by the use of a cooling device.

Bolster plate 100 may be formed integrally. For example, bolster plate 100 may be stamped from a single piece of metal using a stamping press. Bolster plate 100 may include a first member 104, a second member 106, a third member 108, and a fourth member 110. Members 104-110 may be integrally connected. First member 104 may be connected to second member 106 and to fourth member 110. Third member 108 may be connected to second member 106 and to fourth member 110. Members 104 and 108 may have a first length and members 106 and 110 may have a second length that is greater than the first length. Third member 108 may be similar to first member 104. Fourth member 110 may be similar to second member 106. For the purpose of brevity, bolster plate 100 is described with reference to first member 104 and to second member 106.

Bolster plate 100 may include a number of openings to receive fasteners. The openings may enable bolster plate 100 to be mounted on a printed circuit board 112 that houses semiconductor device 102. The openings may also enable a cooling device to interface with semiconductor device 102 by mounting to printed circuit board 112. For example, first member 104 may include an opening 114. Second member 106 may include a first opening 116, a second opening 118, a third opening 120, and a fourth opening 122.

Third opening 120 may be located at a region of bolster plate 100 that intersects first member 104 and second member 106, such as a first corner of bolster plate 100. Fourth opening 122 may be located at a region of bolster plate 100 that intersects second member 106 and third member 108, such as a second corner of bolster plate 100. By having openings 120 and 122 at the intersecting regions, routing traces may be established under a region of second member 106 that is between openings 116 and 118. Openings 114, 120, and 122 may receive distinct fasteners to enable bolster plate 100 to be mounted to printed circuit board 112. Openings 116-118 may receive fasteners to enable a cooling device to interface with semiconductor device 102 via bolster plate 100 by mounting the cooling device to printed circuit board 112.

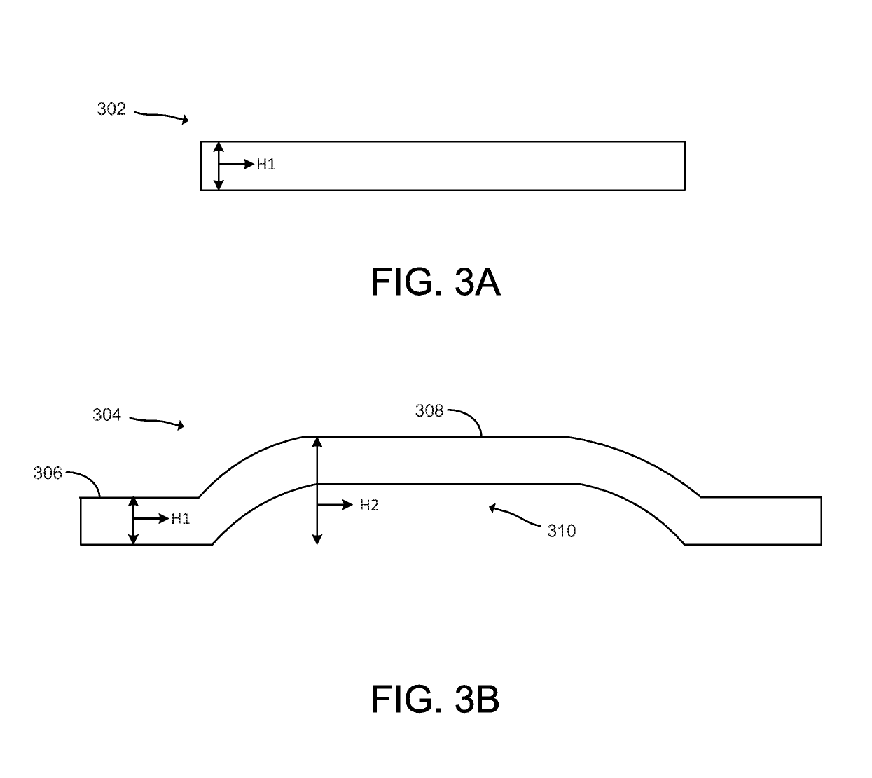

First member 104 may be flat. Thus, first member 104 may be substantially uniform in height. As used herein, substantially uniform in height may include a height variation that is in the range of +/−0.003 inch or 0.00762 centimeter. As described in more detail in FIG. 3A, first member 104 may have a first height. Second member 106 may include a base region 124 having the first height. Base region 124 may be flat and substantially uniform in height. Second member 106 may also include a raised region 126 extending from base region 124. As used herein, base region 124 may include regions of second member 106 besides raised region 126. As described in more detail in FIG. 3B, raised region 126 may have a second height that is greater than the first height. Raised region 126 may be located between openings 116 and 118. In some examples, the second height may not exceed a top surface of an integrated heat spreader 128 of semiconductor device 102.

Raised region 126 may be formed integrally with second member 106. Raised region 126 may increase the structural rigidity of second member 106. Thus, a likelihood of bending of second member 106 due to the mounting force of a cooling device may be reduced. Accordingly, the overall structural rigidity of bolster plate 100 may be increased.

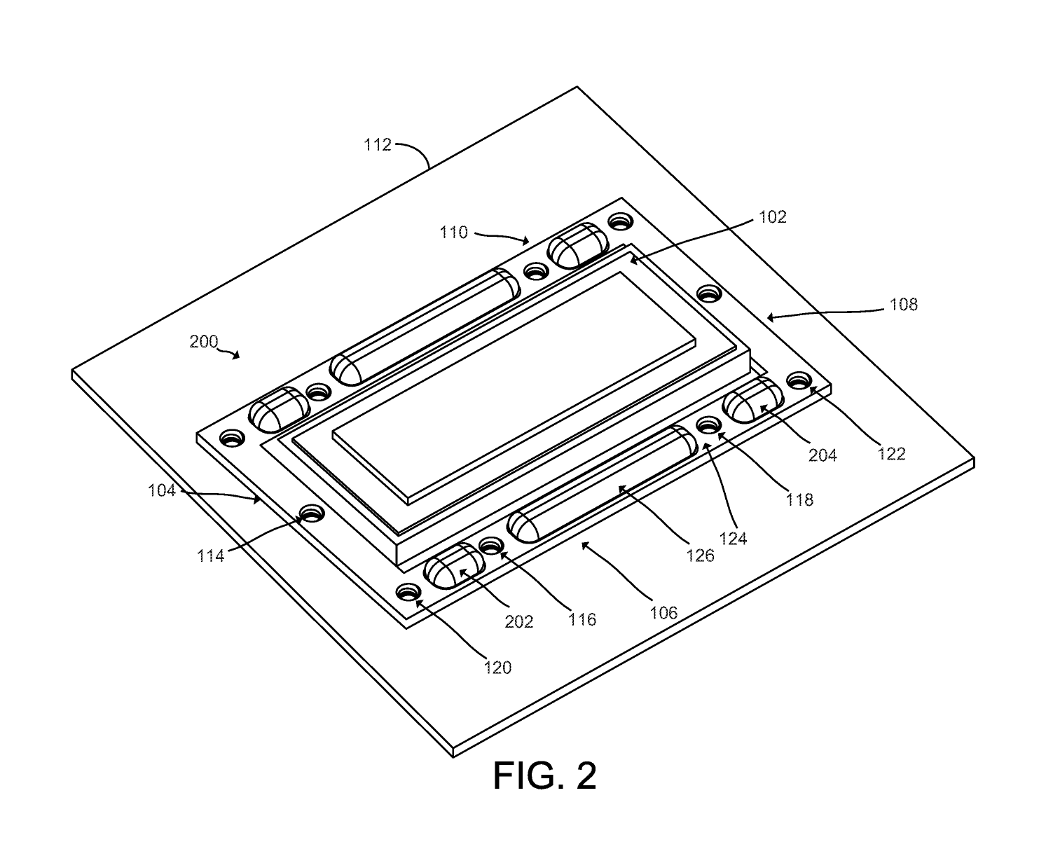

FIG. 2 is a top view of a bolster plate 200, according to another example. Bolster plate 200 may be similar to bolster plate 100 of FIG. 1. However, second member 106 and fourth member 110 may include multiple raised regions. Each raised region may be separated by at least one opening. For example, second member 106 may include raised region 126 between openings 116 and 118. Second member 106 may also include a raised region 202 between openings 120 and 116. Second member 106 may further include a raised region 204 between openings 118 and 122.

FIG. 3A is a cross-section of a member 302 of a bolster plate, according to an example. Member 302 may be similar to first member 104 of bolster plate 100 of FIG. 1, third member 108 of bolster plate 100, first member 104 of bolster plate 200 of FIG. 2, and third member 108 of bolster plate 200. Member 302 may have a first height H1. Member 302 may be substantially uniform in height. Thus, member 302 may have a first cross-sectional shape corresponding to a flat profile.

FIG. 3B is a cross-section of a member 304 of a bolster plate having a base region 306 and a raised region 308, according to an example. Member 304 may be similar to second member 106 of bolster plate 100 of FIG. 1, fourth member 110 of bolster plate 100, second member 106 of bolster plate 200 of FIG. 2, and fourth member 110 of bolster plate 200. Base region 306 may be similar to base region 124 and raised region 308 may be similar to raised region 126.

As illustrated in FIG. 3B, base region 306 may have the first height H1. Raised region 308 may have a second height H2 that is greater than the first height H1. Member 304 may have a second cross-sectional shape corresponding to a step profile define by base region 306 and raised region 308. Raised region 308 may be formed integrally with member 304. In some examples, raised region 308 may be formed via an embossing process. Thus, a region 310 below raised region 308 may be hollow.

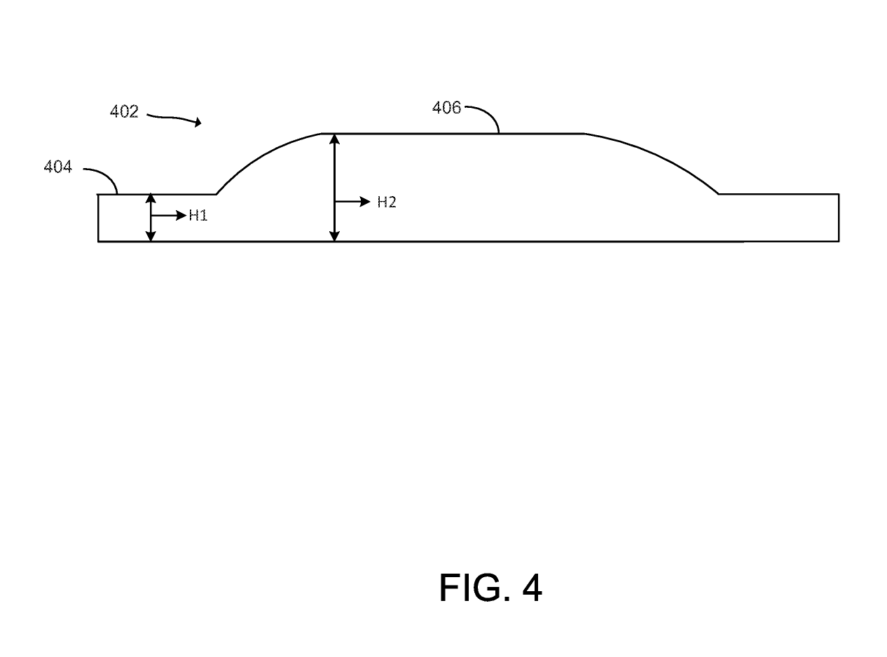

FIG. 4 is a cross-section of a member 402 of a bolsterplate having a base region 404 and a raised region 406, according to another example. Member 402 may be similar to second member 106 of bolster plate 100 of FIG. 1, fourth member 110 of bolster plate 100, second member 106 of bolster plate 200 of FIG. 2, and fourth member 110 of bolster plate 200. Base region 404 may be similar to base region 124 and raised region 406 may be similar to raised region 126. As illustrated in FIG. 4, base region 404 may have the first height H1. Raised region 406 may have the second height H2. Raised region 406 may be formed integrally with member 402. In some examples, raised region 406 may be formed via a stamping process.

According to the foregoing, examples disclosed herein provide a bolster plate to be used with a semiconductor device. The bolster plate may include at least one raised region in one of members of the bolster plate. The raised region may increase the structural rigidity of the bolster plate. Thus, a likelihood of bending of the bolster plate due to the mounting force of a cooling device may be reduced.

The use of “comprising”, “including” or “having” are synonymous and variations thereof herein are meant to be inclusive or open-ended and do not exclude additional unrecited elements or method steps.

What is claimed is:

1. A bolster plate comprising:
a first member having a first height, wherein the first member is substantially uniform in height;
a second member, connected to the first member, including:
a base region having the first height;
a first opening to receive a first fastener;
a second opening to receive a second fastener; and
a raised region extending from the base region between the first opening and the second opening, the raised region having a second height that is greater than the first height;
a third member connected to the second member; and
a fourth member connected to the third member and to the first member, wherein the bolster plate is to receive a cooling device via the first opening and the second opening.

2. The bolster plate of claim 1, the second member further including:
a third opening, located at a first corner intersecting the first member and the second member, to receive a third fastener; and
a fourth opening, located at a second corner intersecting the first member and the fourth member, to receive a fourth fastener, wherein the bolster plate is to connect to a semiconductor device via the third opening and the fourth opening, and wherein the bolster plate is to mount to a printed circuit board housing a semiconductor device via the third opening and the fourth opening.

3. The bolster plate of claim 1, wherein the third member has the first height, wherein the third member is substantially uniform in height, and wherein the fourth member includes:
a second base region having the first height;
a third opening to receive a third fastener;
a fourth opening to receive a fourth fastener; and
a second raised region extending from the second base region between the third opening and the fourth opening, the second raised region having the second height.

4. The bolster plate of claim 1, wherein the first member has a flat profile.

5. The bolster plate of claim 1, wherein the second member has a step profile defined by the base region and the raised region.

6. A bolster plate comprising:
a first member having a first height, wherein the first member is substantially uniform in height, and wherein the first member has a first cross-sectional shape;
a second member, connected to the first member, including:
a base region having the first height; and
a plurality of raised regions extending from the base region, wherein the plurality of raised regions has a second height that is greater than the first height, wherein the second member has a second cross-sectional shape that is different from the first cross-sectional shape;
a third member connected to the second member; and
a fourth member connected to the third member and to the first member.

7. The bolster plate of claim 6, wherein the second member further includes:
a first opening;
a second opening;
a third opening; and
a fourth opening, wherein the plurality of raised regions includes a first raised region, a second raised region, and a third raised region, wherein the first raised region and the second raised region are separated by the first opening, and wherein the second raised region and the third raised region are separated by the second opening, wherein the bolster plate is to receive a cooling device via the first opening and the second opening, and wherein the bolster plate is to mount to a printed circuit board housing a semiconductor device via the third opening and the fourth opening.

8. The bolster plate of claim 8, wherein the third member has the first height, wherein the third member is substantially uniform in height, and wherein the third member has the first cross-sectional shape.

9. The bolster plate of claim 6, wherein the fourth member includes:
a second base region having the first height; and
a second plurality of raised regions extending from the second base region, wherein the second plurality of raised regions has the second height, and wherein the fourth member has the second cross-sectional shape.

10. The bolster plate of claim 6, wherein the first cross-sectional shape is flat, and wherein the second cross-sectional shape has a step profile defined by the base region and one of the plurality of raised regions.

11. A bolster plate comprising:
a first member having a first height, wherein the first member is substantially uniform in height;
a second member, connected to the first member, including:
a base region having the first height;
a first opening;
a second opening;
a third opening;
a fourth opening, wherein the first opening, the second opening, the third opening, and the fourth opening are to receive a distinct fastener;
a first raised region extending from the base region between the first opening and the second opening;
a second raised region extending from the base region between the first opening and the third opening; and
a third raised region extending from the base region between the second opening and the fourth opening, wherein the first raised region, the second raised region, and the third raised region have a second height that is greater than the first height;
a third member connected to the second member; and
a fourth member connected to the third member and to the first. member.

12. The bolster plate of claim 11, wherein the third member has the first height, and wherein the third member is substantially uniform in height.

13. The bolster plate of claim 11, wherein the fourth member includes;
a second base region having the first height;
a fifth opening;
a sixth opening;
a seventh opening;
an eighth opening;
a fourth raised region extending from the second base region between the fifth opening and the sixth opening;
a fifth raised region extending from the second base region between the fifth opening and the seventh opening; and
a sixth raised region extending from the second base region between the sixth opening and the eighth opening, wherein the fourth raised region, the fifth raised region, and the sixth raised region have the second height.

14. The bolster plate of claim 11, wherein the bolster plate is to receive a cooling device via the first opening and the second opening, and wherein the bolster plate is to connect to a semiconductor device via the third opening and the fourth opening, and wherein the bolster plate is to mount to a printed circuit board housing a semiconductor device via the third opening and the fourth opening.

15. The bolster plate of claim 11, wherein the first member, the second member, the third member, and the fourth member are integrally connected.
